(19) United States
(12) Patent Application Publication
(10) Pub. No.: US 2023/0030138 A1
(43) Pub. Date: Feb. 2, 2023

(54) FLOW CONTROL SYSTEM, APPARATUS FOR TREATING SUBSTRATE INCLUDING THE SAME AND METHOD FOR TREATING SUBSTRATE USING THE SAME

(71) Applicant: SEMES CO., LTD., Cheonan-si (KR)

(72) Inventor: KANG SUL KIM, Hwaseong-si (KR)

(73) Assignee: SEMES CO., LTD., Cheonan-si (KR)

(21) Appl. No.: 17/876,506

(22) Filed: Jul. 28, 2022

(30) Foreign Application Priority Data
Jul. 29, 2021 (KR) 10-2021-0099852

(51) Int. Cl. F16L 55/134

(52) U.S. Cl. CPC F16L 55/134

(57) ABSTRACT

The inventive concept provides a flow control system. The flow control system includes a damper provided within the pipe for controlling an opening/closing rate of the pipe by a contraction or an expansion; and a pressure control unit for supplying a gas into the damper or exhausting an inside of the damper, and wherein the pressure control unit includes a pressure control pipe for flowing the gas to/from within the damper through an inlet of the damper.

### CROSS-REFERENCE TO RELATED APPLICATIONS

A claim for priority under 35 U.S.C. § 119 is made to Korean Patent Application No. 10-2021-0099852 filed on Jul. 29, 2021, in the Korean Intellectual Property Office, the entire contents of which are hereby incorporated by reference.

### BACKGROUND

Embodiments of the inventive concept described herein relate to a flow control system, and a substrate treating apparatus including the same and a substrate treating method using the same.

Various processes such as a cleaning, a deposition, a photolithography, an etching, and an ion implantation are performed to manufacture a semiconductor device. These processes are performed in a chamber having a treating space therein.

In general, the treating space of the chamber must maintain a constant process atmosphere. To this end, the treating space is exhausted so that a preset pressure is maintained. Also, a constant airflow is supplied to the treating space so that the preset pressure is maintained. In order to exhaust the treating space or supply an airflow to the treating space, a substrate treating apparatus includes a flow control system. The flow control system has a pipe for exhausting the treating space or supplying the airflow to the treating space.

Each pipe is provided with a damper for adjusting a cross-sectional area of the pipe to control a flow rate of a gas exhausted from the chamber or the flow rate of the gas introduced into the chamber. FIG. 1 illustrates a conventional damper 3. The conventional damper 3 has a rotation shaft 34 and a plate 32, and the plate is provided to adjust the cross-sectional area of the pipe by rotating around the rotation shaft 34.

However, in order to secure a space for rotating the plate 32, an empty space A is formed between the plate 32 and an inner wall of the pipe 1. Accordingly, there is a problem in that the airflow inside the pipe 1 may not be accurately adjusted by the airflow flowing through the empty space A.

In addition, process by-products are accumulated at the plate 32 so that the airflow inside the pipe 1 cannot be accurately controlled. Accordingly, there is a problem that the process by-products accumulated in the plate 32 must be removed, but this cannot be solved without dismantling the pipe 1.

### SUMMARY

Embodiments of the inventive concept provide a flow control system, and a substrate treating apparatus including the same and a substrate treating method using the same for accurately controlling a pressure within a pipe.

Embodiments of the inventive concept provide a flow control system, and a substrate treating apparatus including the same and a substrate treating method using the same for conveniently removing process by-products which have accumulated in a damper.

The technical objectives of the inventive concept are not limited to the above-mentioned ones, and the other unmentioned technical objects will become apparent to those skilled in the art from the following description.

The inventive concept provides a flow control system for controlling a flow rate of a gas moving within a pipe. The flow control system includes a damper provided within the pipe for controlling an opening/closing rate of the pipe by a contraction or an expansion; and a pressure control unit for supplying a gas into the damper or exhausting an inside of the damper, and wherein the pressure control unit includes a pressure control pipe for flowing the gas to/from within the damper through an inlet of the damper.

In an embodiment, the damper is provided as an elastic body.

In an embodiment, the damper is provided in a spherical form.

In an embodiment, the pressure control pipe is provided fixable to an inner wall of the pipe.

In an embodiment, the pressure control pipe includes: a fixing part for fixing to an inner wall of the pipe; and a bending part extending and bending from the fixing part, and coupled to the inlet.

In an embodiment, the bending part and the pipe are provided parallel to each other.

In an embodiment, the flow control system further includes a sealing member for connecting and sealing the bending part and a top or a bottom of a central region of the damper.

In an embodiment, the pressure control unit further includes: a pressure measuring device for measuring a pressure within the pipe at a front end of the damper; a regulator for adjusting a pressure of a gas flowing to/from within the damper; and a controller for controlling the regulator based on a pressure within the pipe measured at the pressure measuring device.

The inventive concept provides a substrate treating apparatus. The substrate treating apparatus includes a plurality of process chambers having a treating space within and treating a substrate within the treating space; and a pipe unit for supplying a gas to the treating space or exhausting the treating space, and wherein the pipe unit includes: a plurality of pipes directly connected to the treating space of one or more process chambers; an integrated pipe connected to the plurality of pipes; and a flow control system for controlling a flow rate of a gas moving within the pipe, and wherein the flow control system includes: a damper provided within the pipe and controlling an opening/closing rate of the pipe by a volume change; a pressure control unit for supplying the gas into the damper or exhausting an inside of the damper, and wherein the pressure control unit includes a pressure control pipe for flowing the gas to/from within the damper through an inlet of the damper.

In an embodiment, the damper is provided as an elastic body.

In an embodiment, the damper is provided in a spherical form.

In an embodiment, the pressure control pipe is provided fixable to an inner wall of the pipe.

In an embodiment, the pressure control pipe includes: a fixing part for fixing to an inner wall of the pipe; and a bending part extending and bending from the fixing part, and coupled to the inlet of the damper.

In an embodiment, the bending part and the pipe are provided parallel to each other.

In an embodiment, further includes a sealing member for connecting and sealing the bending part and a top or a bottom of a central region of the damper.

In an embodiment, the pressure control unit further includes: a pressure measuring device for measuring a pressure within the pipe at a front end of the damper; a regulator for adjusting a pressure of a gas flowing to/from within the damper; and a controller for controlling the regulator based on a pressure within the pipe measured at the pressure measuring device.

In an embodiment, the controller controls the regulator so a pressure of within each pipe is substantially the same, while the substrate is treated within a process chamber.

The inventive concept provides a substrate treating method using the substrate treating apparatus. The substrate treating method includes treating the substrate within a process chamber, which is a substrate treating step; and removing particles on the damper, which is a particle removing step, and wherein in the particle removing step, the damper is repeatedly contracted and expanded.

In an embodiment, in the substrate treating step, a pressure within each pipe is controlled to be substantially the same.

In an embodiment, the particle removing step is performed before and after the substrate treating step.

According to an embodiment of the inventive concept, a pressure within a pipe can be accurately adjusted.

According to an embodiment of the inventive concept, process by-products accumulated in a damper may be conveniently removed.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a cross-sectional view schematically illustrating a conventional damper provided in a pipe.

FIG. 2 is a cross-sectional view schematically illustrating a flow control system provided in the pipe according to an embodiment of the inventive concept.

FIG. 3 to FIG. 4 are cross-sectional views illustrating a state in which the damper of the inventive concept is contracted or expanded, respectively.

FIG. 5 schematically illustrates a substrate treating apparatus according to an embodiment of the inventive concept.

FIG. 6 to FIG. 8 are views sequentially illustrating a particle removing step according to an embodiment of the inventive concept.

FIG. 9 is a cross-sectional view schematically illustrating a flow control system provided in the pipe according to an embodiment of the inventive concept.

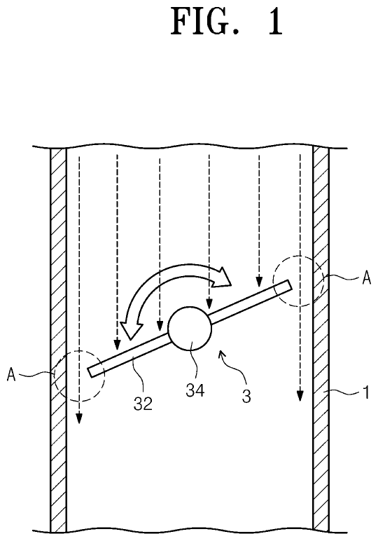

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

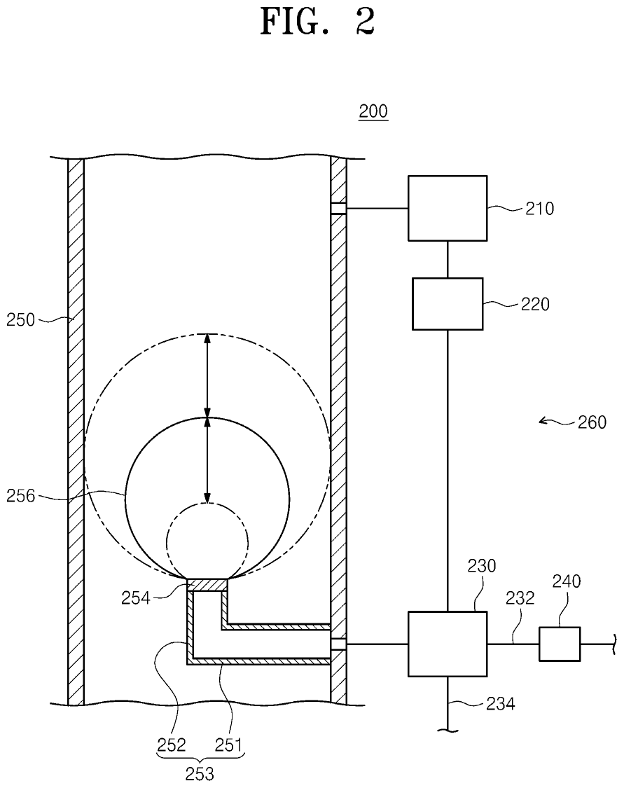

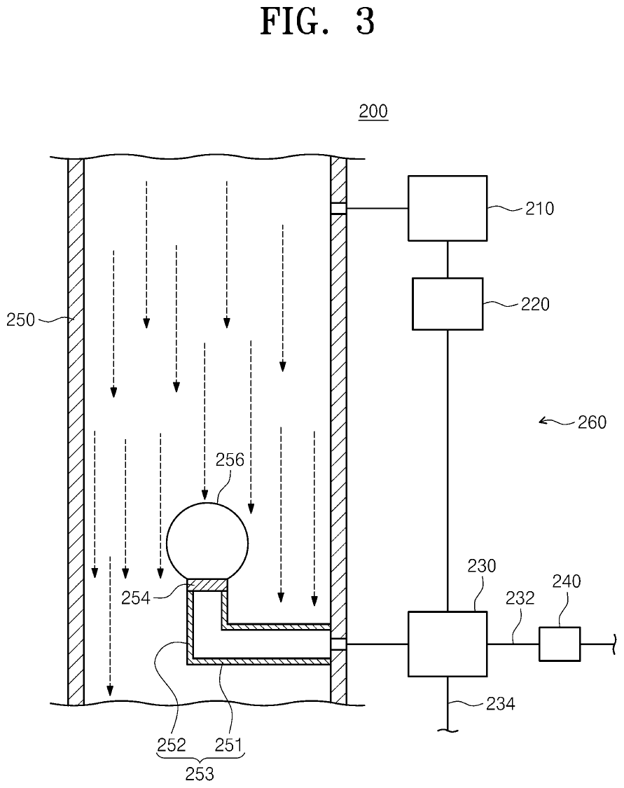

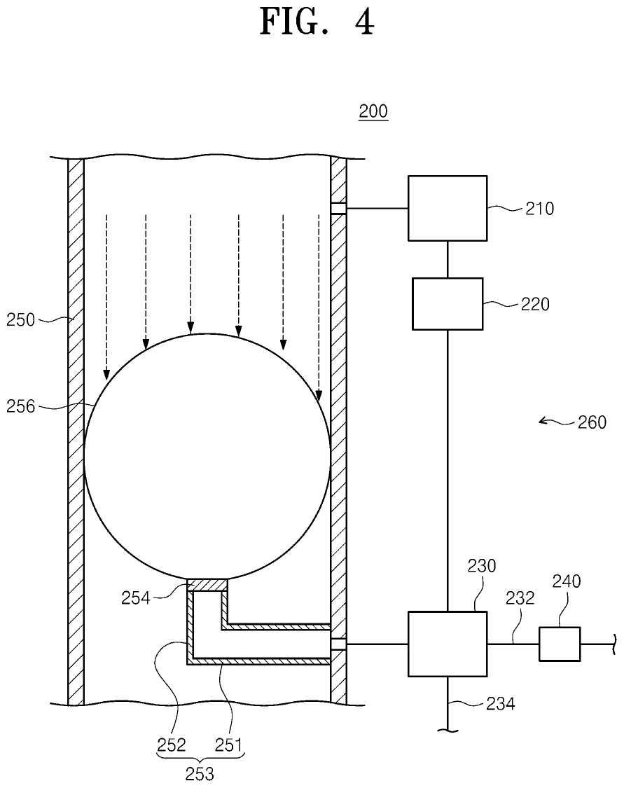

FIG. 2 is a cross-sectional view schematically illustrating a flow control system 200 provided in a pipe 250 according to an embodiment of the inventive concept, and FIG. 3 to FIG. 4 are cross-sectional views illustrating a damper 256 of the inventive concept contracted or expanded, respectively.

Referring to FIG. 2 to FIG. 4, the flow control system 200 has a damper 256 and a pressure control unit 260. The damper 256 is provided inside the pipe 250 to control a pressure inside the pipe 250 by adjusting an opening/closing rate of the pipe 250. The damper 256 adjusts the opening/closing rate of the pipe 250 by a contraction or an expansion. In an embodiment, the damper 256 may be provided as an elastic body. In an embodiment, the damper 256 is provided in a spherical form. The damper 256 has an inner space capable of storing a gas therein. For example, the damper 256 may have a shape such as a balloon. In an embodiment, the damper 256 is provided to expand to a volume capable of blocking an entire pipe 250. Accordingly, when it is necessary to completely close the pipe 250, the damper 256 may completely close the entire pipe 250

In an embodiment, the damper 256 has an inlet on a side. The gas flows in and out of the inner space of the damper 256 through the inlet. The pressure control unit 260 supplies the gas to the inner space of the damper 256 or exhausts the inner space of the damper 256. In an embodiment, the pressure control unit 260 includes a pressure control pipe 253, a pressure measuring device 210, a regulator 230, and a controller 220.

The pressure control pipe 253 flows the gas in and out of the inner space of the damper 256. In an embodiment, the pressure control pipe 253 may be provided to be fixed to an inner wall of the pipe 250. In an embodiment, the pressure control pipe 253 has a fixing part 251, a bending part 252, and a sealing member 254. The fixing part 251 is fixed to an inner wall of the pipe 250. The bending part 252 extends and bends from the fixing part 251 and is coupled to the inlet of the damper 256. In an embodiment, the bending part 252 and the pipe 250 may be provided parallel to each other. The sealing member 254 connects and seals the bending part 252 and a top or a bottom of a central region of the damper 256. In an embodiment, the sealing member 254 is made of a sealable material, but is made of a material hard enough to fix the damper 256 to the pressure control pipe 253 near the inlet. As the pressure control pipe 253 connected to the damper 256 is provided to be fixed to the inner wall of the pipe 250 and the inlet is provided to be fixed to the pressure control pipe 253, the inlet is placed in the pipe 250 regardless of a contraction or an expansion of the damper 256.

A gas supply line 232, a regulator 230, and a gas supply source 240 are connected to the pressure control pipe 253. The gas supply line 232 supplies the gas from the gas supply source 240 to the pressure control pipe 253.

The pressure measuring device 210 measures the pressure inside the pipe 250. In an embodiment, the pressure measuring device 210 measures the pressure inside the pipe 250 at a front end of the damper. That is, the pressure measuring device 210 measures an inner pressure of the pipe 250 at the front end of the damper 256, and adjusts the pressure in the pipe 250 through the damper 256. The pressure measuring device 210 transmits a measured pressure information to the controller 220. The regulator 230 adjusts a pressure of the gas flowing in and out of the damper 256. In an embodiment, the regulator 230 may be provided as an electrostatic regulator 230. The controller 220 controls the regulator 230 based on the pressure inside the pipe 250 measured from the pressure measuring device 210

In an embodiment, when the pressure measured by the pressure measuring device 210 is higher than the preset pressure, the damper 256 is contracted as shown in FIG. 3 to increase the opening/closing rate of the pipe 250. In an embodiment, when the pressure measured by the pressure measuring device 210 is lower than the preset pressure, the damper 256 is expanded to lower the opening/closing rate of the pipe 250.

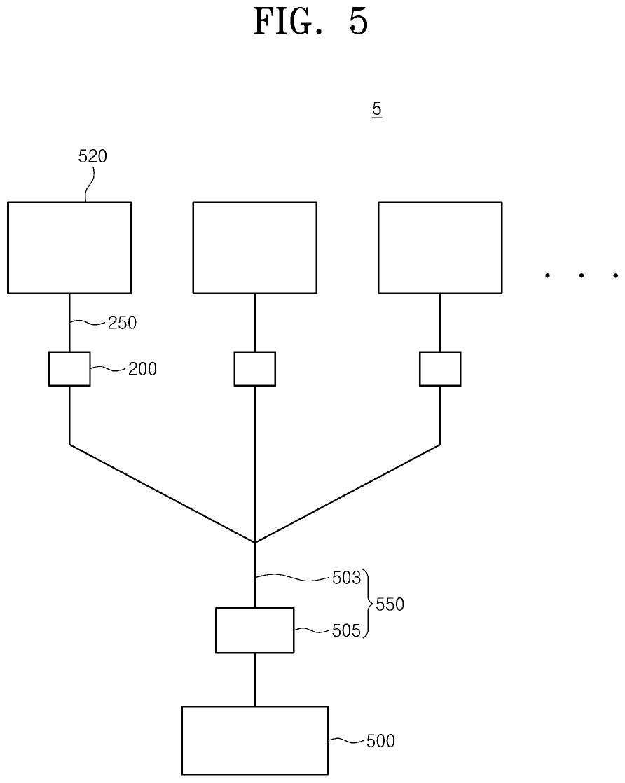

FIG. 5 schematically illustrates a substrate treating apparatus 5 according to an embodiment of the inventive concept.

The substrate treating apparatus 5 includes a plurality of process chambers 520 and a pipe unit 550. A process chamber 520 has a treating space therein and a substrate is treated in the treating space. Also, the process chamber 520 may be provided with a container in which the substrate is stored, or a device for transferring the substrate therein may be provided.

The pipe unit 550 supplies a gas to the treating space or exhausts the treating space. The pipe unit 550 includes a pipe 250, an integrated pipe 503, and a flow control system 200. In an embodiment, each pipe 250 and the flow control system 200 are provided as the pipe 250 and the flow control system 200 of FIG. 2. The pipe 250 is directly connected to the treating space of one or more process chambers 520. A plurality of pipes 250 are connected to the integrated pipe 503. In an embodiment, the integrated pipe 503 may connect a plurality of process chambers 520 to the factory facility 500. A pipe damper 505 may be installed at the integrated pipe 503. However, since a pressure inside the plurality of pipes 250 may be different from each other, it is difficult to control an airflow flowing into the factory facility 500 only with the through the pipe damper 505. Accordingly, the inventive concept adjusts the airflow of each of the pipes 250 through the flow control system 200.

In an embodiment, a substrate treating method of the inventive concept includes a substrate treating step and a particle removing step.

In the substrate treating step, the substrate is treated in the process chamber 520. While the substrate treating step is performed, the pressure in the pipe 250 is adjusted through the flow control system 200. In an embodiment, when the pressure measured by the pressure measuring device 210 is higher than a preset pressure, the damper 256 is contracted to increase an opening/closing rate of the pipe 250. In an embodiment, when the pressure measured by the pressure measuring device 210 is lower than the preset pressure, the damper 256 is expanded to lower the opening/closing rate of the pipe 250. In an embodiment, in the substrate treating step, the preset pressure inside each pipe 250 may be provided equally. Accordingly, there is an advantage in that it is easy to control an airflow flowing into the factory facility 500 from the integrated pipe 503. In an embodiment, the opening/closing rate of the pipe 250 may be a ratio of a diameter of pipe 250 and a diameter of the damper 256. The diameter of the damper may be determined according to a pressure of the gas within the damper 256. In an embodiment, the gas supplied to the damper 256 or exhausted from the damper 256 may include or may be an inert gas such as argon (Ar) gas and nitrogen (N2) gas. The present invention, however, is not limited thereto. Various gases may be supplied to or exhausted from the damper 256 to control the volume of the damper 256. In an embodiment, through the pipe 250, a clean dry air with a controlled temperature and humidity for a process may be supplied to the process chamber 520, and a by-product gas or organic fume generated in the process may be exhausted from the process chamber 520.

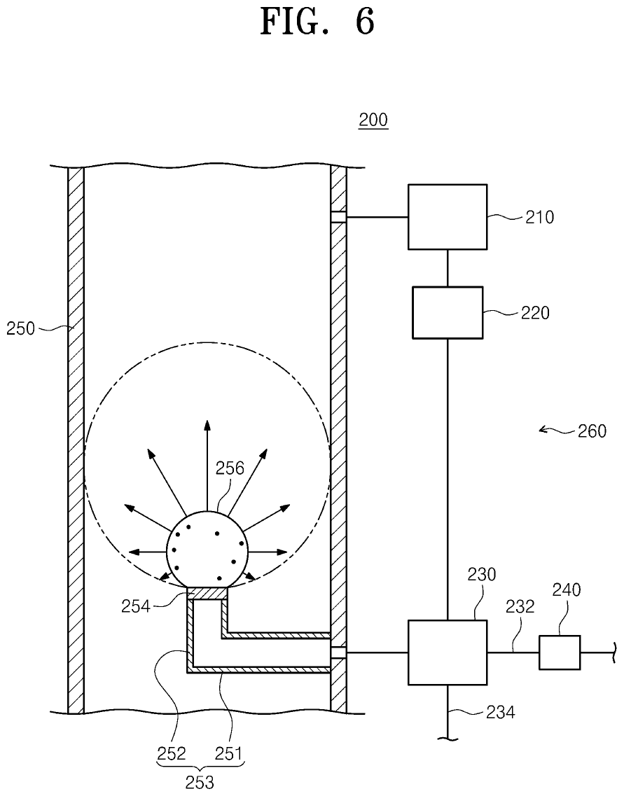

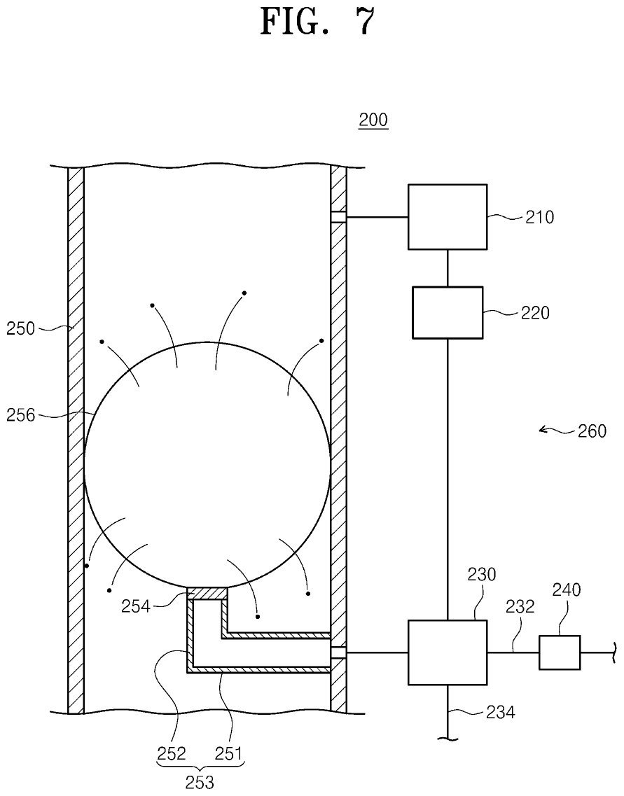

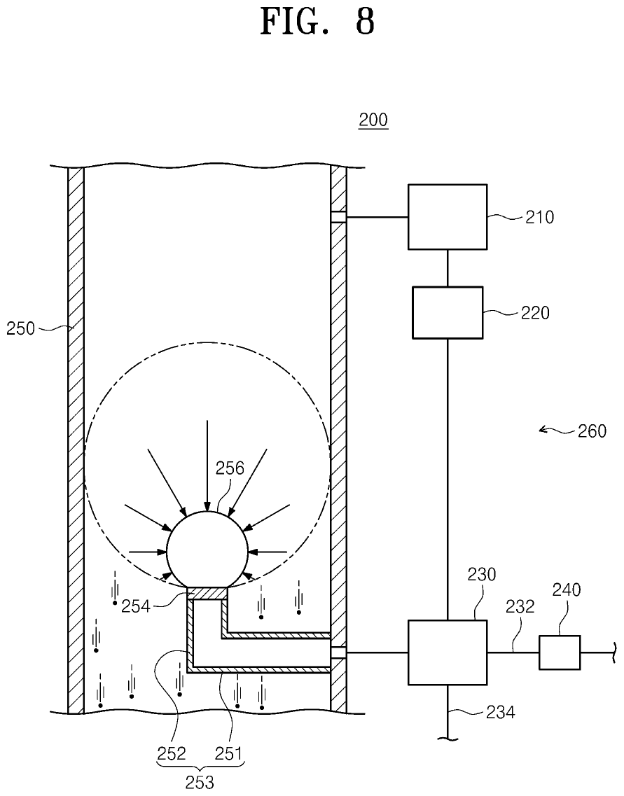

The particle removing step may be performed before or after the substrate treating step. FIG. 6 to FIG. 8 are views sequentially illustrating a particle removing step of the inventive concept. In the particle removing step, particles on the damper 256 are removed. In the particle removing step, as in the substrate treating step, an airflow is formed in the pipe 250 in a direction from the process chamber 520 to the factory facility 500. In the particle removing step, the damper 256 may be repeatedly contracted and expanded. For example, as illustrated in FIG. 6, the damper 256 is inflated. In the process of expanding the damper 256, particles bounce off of a surface of the damper 256 as illustrated in FIG. 7. Thereafter, when the damper 256 is contracted again as shown in FIG. 8, particles bounced off the surface of the damper 256 flow downstream by the airflow formed in the pipe 250. In the particle removing step, the particles on the damper 256 are removed by repeating the process of FIG. 6 to FIG. 8 several times.

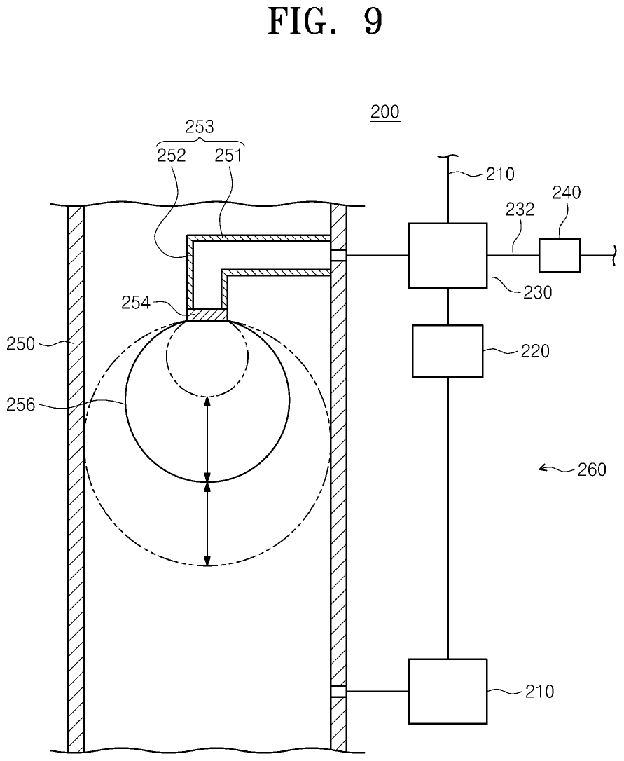

In FIG. 2, it has been described that a sealing member 254 is coupled to a bottom portion of the damper 256. However, unlike this, as illustrated in FIG. 9, the sealing member 254 may be provided to be coupled to the top portion of the damper 256.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A flow control system for controlling a flow rate of a gas moving within a pipe, the flow control system comprising:
a damper provided within the pipe for controlling an opening/closing rate of the pipe by a contraction or an expansion of the damper; and
a pressure control unit for supplying a gas into the damper or exhausting the gas from an inside of the damper,
wherein the pressure control unit includes a pressure control pipe connected to an inlet of the damper and flowing the gas to the damper or from the damper through the inlet of the damper.

2. The flow control system of claim 1,
wherein the damper is provided as an elastic body.

3. The flow control system of claim 1,
wherein the damper is provided in a spherical form.

4. The flow control system of claim 1,
wherein the pressure control pipe is attached to an inner wall of the pipe.

5. The flow control system of claim 1,
wherein the pressure control pipe comprises:
a fixing part for fixing to an inner wall of the pipe; and
a bending part extending and bending from the fixing part, and coupled to the inlet.

6. The flow control system of claim 5,
wherein the bending part and the pipe are provided parallel to each other.

7. The flow control system of claim 5, further comprising:
a sealing member for connecting and sealing the bending part and a top or a bottom of a central region of the damper.

8. The flow control system of claim 1,
wherein the pressure control unit further comprises:
a pressure measuring device for measuring a pressure within the pipe at a front end of the damper;
a regulator for adjusting a pressure of a gas flowing to/from within the damper; and
a controller for controlling the regulator based on a pressure within the pipe measured at the pressure measuring device.

9. A substrate treating apparatus comprising:
a plurality of process chambers having a treating space within and treating a substrate within the treating space; and
a pipe unit for supplying a first gas to the treating space or exhausting a second gas from the treating space,
wherein the pipe unit comprises:
a plurality of pipes directly connected to the treating space of the plurality of process chambers, respectively;
an integrated pipe connected to the plurality of pipes; and
a plurality of flow control systems provided at the plurality of pipes, respectively,
wherein each flow control system of the plurality of flow control systems controls a flow rate of a gas moving within a corresponding pipe of the plurality of pipes,
wherein each flow control system of the plurality of flow control systems comprises:
a damper provided within the pipe and controlling an opening/closing rate of a corresponding pipe of the plurality of pipes by a volume change of the damper;
a pressure control unit for supplying a third gas into the damper or exhausting the third gas from an inside of the damper, and
wherein the pressure control unit includes a pressure control pipe connected to an inlet of the damper and flowing the third gas to the damper or from the damper through the inlet of the damper.

10. The substrate treating apparatus of claim 9,
wherein the damper is provided as an elastic body.

11. The substrate treating apparatus of claim 9,
wherein the damper is provided in a spherical form.

12. The substrate treating apparatus of claim 9,
wherein the pressure control pipe is attached to an inner wall of the corresponding pipe of the plurality of pipes.

13. The substrate treating apparatus of claim 9,
wherein the pressure control pipe comprises:
a fixing part for fixing to an inner wall of a corresponding pipe of the plurality of pipes; and
a bending part extending and bending from the fixing part, and coupled to the inlet of the damper.

14. The substrate treating apparatus of claim 13,
wherein the bending part and the corresponding pipe of the plurality of pipes are provided parallel to each other.

15. The substrate treating apparatus of claim 13 further comprising:
a sealing member for connecting and sealing the bending part and a top or a bottom of a central region of the damper.

16. The substrate treating apparatus of claim 9,
wherein the pressure control unit further comprises:
a pressure measuring device for measuring a pressure within the corresponding pipe of the plurality of pipes at a front end of the damper;
a regulator for adjusting a pressure of a gas flowing to/from within the damper; and
a controller for controlling the regulator based on a pressure within the corresponding pipe of the plurality of pipes measured at the pressure measuring device.

17. The substrate treating apparatus of claim 16,
wherein the controller controls the regulator to cause each pipe of the plurality of pipes to have substantially the same pressure, while the substrate is treated within a corresponding process chamber of the plurality of process chambers.

18.-20. (canceled)

21. The flow control system of claim 1,
wherein the opening/closing rate of the pipe is a ratio of a diameter of pipe and a diameter of the damper, and
wherein the diameter of the damper is determined according to a pressure of the gas within the damper.

22. The flow control system of claim 1,
wherein the gas is an inert gas.
